(19) United States
(12) Patent Application Publication
(10) Pub. No.: US 2021/0116243 A1
(43) Pub. Date: Apr. 22, 2021

(54) SENSOR

(71) Applicant: PANASONIC INTELLECTUAL PROPERTY MANAGEMENT CO., LTD., Osaka (JP)

(72) Inventors: Katsuya MORINAKA, Osaka (JP); Kaoru TONE, Osaka (JP)

(21) Appl. No.: 17/136,750

(22) Filed: Dec. 29, 2020

Related U.S. Application Data
(62) Division of application No. 16/075,127, filed on Aug. 2, 2018.

(30) Foreign Application Priority Data
Mar. 22, 2016 (JP) 2016-056462
Mar. 23, 2016 (JP) 2016-057961

(51) Int. Cl. G01C 19/5663; G01P 3/44; G01P 15/16; G01P 1/04; G01P 15/08; G01C 19/5747; G01C 19/5783; H01L 41/113

(52) U.S. Cl. CPC G01C 19/5663; G01P 3/44; G01P 15/165; H01L 41/1132; G01P 15/08; G01C 19/5747; G01C 19/5783; G01P 1/04

(57) ABSTRACT

A disclosed sensor includes a substrate, a substrate electrode, a sensor element, a sensor electrode, and a connection member. The substrate has a main face. The substrate electrode is disposed on the main face. The sensor element has a first face perpendicular to the main face, and detects an angular velocity about an axis parallel to the main face. The sensor electrode is disposed on the first face of the sensor element. The connection member connects the substrate electrode and the sensor electrode. The width of the sensor electrode at a position closer to the main face is smaller than the width of the sensor electrode at a position farther from the main face.

### CROSS-REFERENCE OF RELATED APPLICATIONS

This application is a Divisional application of U.S. patent application Ser. No. 16/075,127, filed on Aug. 2, 2018, which is a U.S. National Phase under 35 U.S.C. § 371 of International Patent Application No. PCT/JP2017/008405, filed on Mar. 3, 2017, which in turn claims the benefit of Japanese Patent Application No. 2016-057961, filed on Mar. 23, 2016 and Japanese Application No. 2016-056462, filed on Mar. 22, 2016, the entire disclosures of which Applications are incorporated by reference herein.

### TECHNICAL FIELD

The present disclosure relates to a sensor used in, for example, an electronic device.

### BACKGROUND ART

Conventionally, a sensor is known in which a sensor element is mounted perpendicularly to the main face of the substrate. For example, Patent Literature (PTL) 1 is known as a document disclosing a conventional technology related to the invention of the present application.

### CITATION LIST

### Patent Literature

PTL 1: Japanese Unexamined Patent Application Publication No. 2010-169614
PTL 2: Japanese Unexamined Patent Application Publication No. 2016-14653
PTL 3: Japanese Unexamined Patent Application Publication No. 2015-166748
PTL 4: Japanese Unexamined Patent Application Publication No. 2015-165240
PTL 5: Japanese Unexamined Patent Application Publication No. 2009-162760

### SUMMARY

A sensor according to the present disclosure includes a substrate, a substrate electrode, a sensor element, a sensor electrode, and a connection member.

The substrate has a main face.

The substrate electrode is disposed on the main face.

The sensor element has a first face perpendicular to the main face, and detects an angular velocity about an axis parallel to the main face.

The sensor electrode is disposed on the first face of the sensor element.

A connection member connects the substrate electrode and the sensor electrode.

The width of the sensor electrode at a position closer to the main face is smaller than the width of the sensor electrode at a position farther from the main face.

### BRIEF DESCRIPTION OF THE DRAWINGS

FIG. 1A is a top view of a sensor according to an embodiment.

FIG. 1B illustrates a cross-section taken along line 1B-1B in FIG. 1A.

FIG. 2 is a schematic cross-sectional view of a sensor element and a substrate according to the embodiment.

FIG. 3 is a schematic perspective view of the sensor element and the substrate according to the embodiment.

FIG. 4 is an exploded schematic perspective view of another sensor element and a substrate according to the embodiment.

FIG. 5 is a schematic cross-sectional view taken along line 5-5 in a state where the substrate and the sensor element in FIG. 4 are combined.

FIG. 6 is a schematic perspective view of yet another sensor element and a substrate according to the embodiment.

FIG. 7 is a schematic cross-sectional view taken along line 7-7 in FIG. 6.

FIG. 8 is a schematic perspective view of yet another sensor element and a substrate according to the embodiment.

FIG. 9A illustrates a variation of a sensor electrode according to the embodiment.

FIG. 9B illustrates another variation of the sensor electrode according to the embodiment.

FIG. 9C illustrates another variation of the sensor electrode according to the embodiment.

FIG. 9D illustrates another variation of the sensor electrode according to the embodiment.

FIG. 10A is a top view of yet another sensor according to the embodiment.

FIG. 10B illustrates a cross-section taken along line 10B-10B in FIG. 10A.

FIG. 11 is a schematic cross-sectional view of yet another sensor element and a substrate according to the embodiment.

FIG. 12 is a schematic perspective view of yet another sensor element and a substrate according to the embodiment.

FIG. 13A is a front view of yet another sensor element according to the embodiment.

FIG. 13B is a front view of yet another sensor element according to the embodiment.

FIG. 13C is a front view of yet another sensor element according to the embodiment.

FIG. 14A is a front view of yet another sensor element according to the embodiment.

FIG. 14B is a front view of yet another sensor element according to the embodiment.

FIG. 14C is a front view of yet another sensor element according to the embodiment.

FIG. 15A is an oblique projection view of yet another sensor element according to the embodiment.

FIG. 15B is an oblique projection view of the sensor element in FIG. 15A viewed from the bottom side of the sensor element.

FIG. 16A is a top view of yet another sensor element.

FIG. 16B is a front view of the sensor element in FIG. 16A.

FIG. 16C is a bottom view of the sensor element in FIG. 16A.

FIG. 16D is a side view of the sensor element in FIG. 16A.

FIG. 16E is a cross-sectional view taken along line 16E-16E in FIG. 16B.

FIG. 16F is an enlarged view of the area circled by the dashed line in FIG. 16E.

FIG. 16G is an enlarged view of the area circled by the dashed line in FIG. 16B.

### DESCRIPTION OF EMBODIMENT

The sensor electrodes in a sensor element in a conventional sensor often do not extend to the end face of the sensor element. This is because if the sensor electrodes extend to the end face of the sensor element, the sensor electrodes may peel off when the sensor element is cut. If the sensor electrodes do not extend to the end face of the sensor element, when the sensor electrodes and the substrate electrodes on the substrate are connected, solders may not sufficiently reach the sensor electrodes. In particular, when the sensor element is mounted perpendicularly to the substrate, if the sensor element is mounted obliquely to the main face of the substrate, the connection may be insufficient. In other words, insufficient precision in mounting angle leads to insufficient connection, resulting in a reduction in sensor precision.

Moreover, since the conventional sensor is small in width, it is difficult to mount the sensor element perpendicularly to the substrate with high precision.

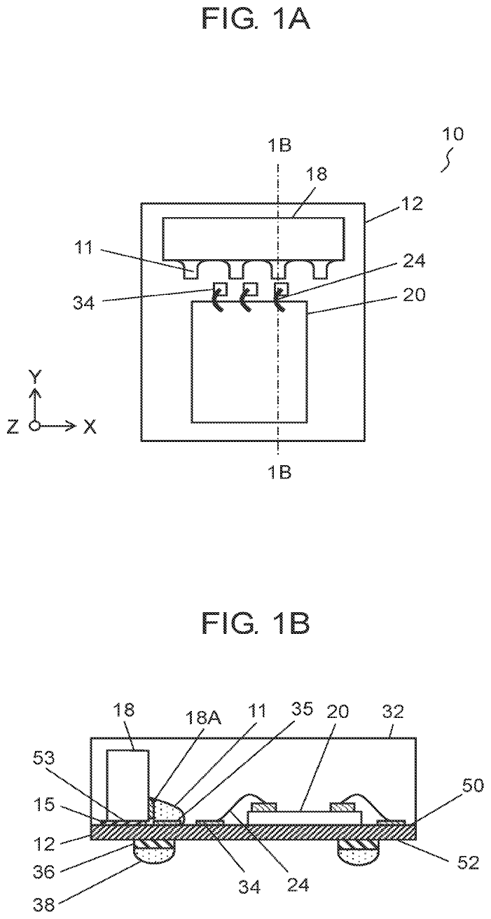

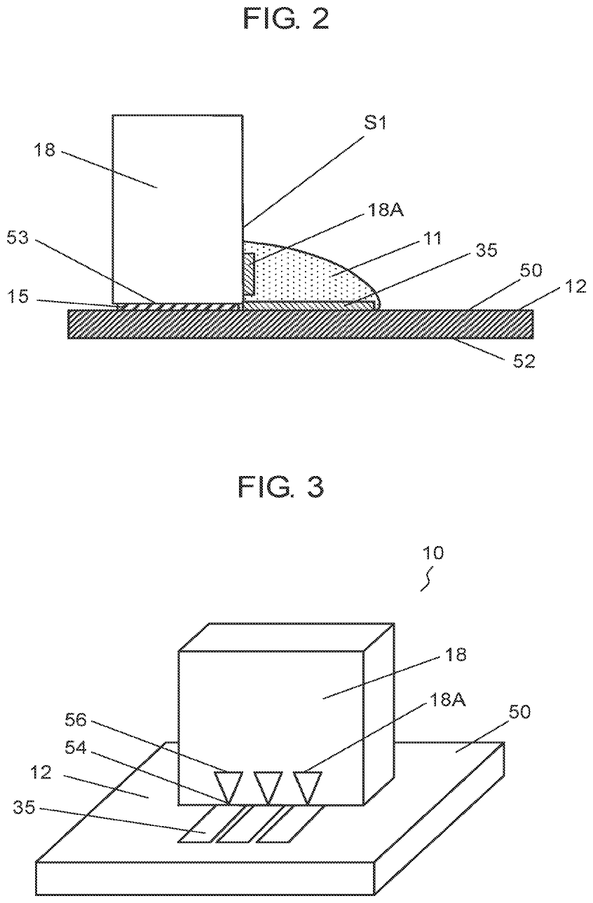

Hereinafter, a sensor according to an embodiment of the present disclosure will be described with reference to the drawings. FIG. 1A is a top view of sensor 10 according to the embodiment. FIG. 1B illustrates a cross-section taken along line 1B-1B in FIG. 1A. FIG. 2 is a schematic cross-sectional view of sensor element 18 and substrate 12 according to the embodiment. FIG. 3 is a schematic perspective view of sensor element 18 and substrate 12 according to the embodiment. In FIG. 1A, the x-axis is parallel to main face 50 (top face) of substrate 12. The y-axis is parallel to main face 50 of substrate 12, and orthogonal to the x-axis. The z-axis is perpendicular to main face 50 of substrate 12.

Sensor 10 includes substrate 12, substrate electrodes 35, sensor element 18, sensor electrodes 18A, and connection members 11.

Substrate 12 has main face 50.

Substrate electrodes 35 are disposed on main face 50.

Sensor element 18 has first face 51 perpendicular to main face 50, and detects the angular velocity about an axis parallel to main face 50.

Sensor electrodes 18A are disposed on first face 51 of sensor element 18.

Connection members 11 connect substrate electrodes 35 and sensor electrodes 18A.

As illustrated in FIG. 3, the width of each of sensor electrodes 18A at a position closer to main face 50 is smaller than the width of sensor electrode 18A at a position farther from main face 50.

Here, the term “perpendicular” is not limited to being exactly 90 degrees, but may be approximately 90 degrees. For example, it may be 90 degrees±10 degrees approximately.

Moreover, here, the term “position closer to main face 50” may indicate the position of sensor electrode 18A closest to main face 50. Moreover, the term “position farther from main face 50” may indicate the position of sensor electrode 18A farthest from main face 50.

Alternatively, the term “position closer to main face 50” may indicate the position closest to main face 50 when sensor electrode 18A is equally divided into 10 parts in the longitudinal direction of sensor electrode 18A (along the z-axis). Moreover, the term “position farther from main face 50” may indicate the position farthest from main face 50 when sensor electrode 18A is equally divided into 10 parts in the longitudinal direction of sensor electrode 18A (along the z-axis).

Moreover, the term “width” includes the case of “point”. For example, when sensor electrode 18A has a triangular shape having a vertex angle toward main face 50 as illustrated in FIG. 3, the position of sensor electrode 18A closest to main face 50 is apex 54 of the triangle. In such a case, “the width of sensor electrode 18A at a position closer to main face 50” may be a point. Moreover, in FIG. 3, the position of sensor electrode 18A farthest from main face 50 is line segment 56. In other words, in the present embodiment, the width (apex 54) of sensor electrode 18A at a position closer to main face 50 is smaller than the width (line segment 56) of sensor electrode 18A at a position farther from main face 50.

Hereinafter, sensor 10 will be described in detail. Sensor 10 includes substrate 12, sensor element 18, and solders 11 (connection members). Sensor element 18 is disposed on main face 50 of substrate 12. Solders 11 connect substrate 12 and sensor element 18. Sensor 10 may further include semiconductor element 20 and sealing resin 32. Semiconductor element 20 is disposed on main face 50 of substrate 12. Sealing resin 32 is disposed on main face 50 of substrate 12 so as to cover sensor element 18 and semiconductor element 20.

Substrate 12 is made of, for example, resin such as glass epoxy. Substrate electrodes 35 are disposed on main face 50 (top face) of substrate 12. Bottom electrodes 36 are disposed on bottom face 52 of substrate 12. Substrate electrodes 35 and bottom electrodes 36 are electrically connected to each other. Solder bumps 38 are disposed on bottom electrodes 36.

Sensor element 18 detects the physical quantity (angular velocity) about the x-axis. In other words, sensor element 18 detects the physical quantity (angular velocity) about an axis parallel to main face 50 of substrate 12. Various structures can be used for sensor element 18. For example, sensor elements described in PTL 2 to PTL 5 may be used. Note that the physical quantity detected by sensor element 18 is not limited to the angular velocity, but may be acceleration. In other words, sensor element 18 may be described as an inertial force detection element which detects the physical quantity such as angular velocity or acceleration.

Bottom face 53 of sensor element 18 is fixed to the top face of substrate 12 via adhesive material 15 made of epoxy resin or the like.

Bottom face 53 of sensor element 18 is fixed to the top face of substrate 12 via adhesive material 15. Adhesive material 15 is an adhesive material made of a resin material such as epoxy resin. Adhesive material 15 is formed by being applied onto main face 50 of substrate 12 in a liquid state or a semisolid state and undergoing heat curing.

Sensor electrodes 18A are disposed on first face 51 of sensor element 18. Sensor electrodes 18A are connected to substrate electrodes 35 via solders 11.

Semiconductor element 20 is mounted near the central portion of main face 50 of substrate 12. Pads 34 and thin metal lines 24 are also disposed on main face 50. Semiconductor element 20 is connected to sensor element 18 via pads 34 and thin metal lines 24. Semiconductor element 20 includes a circuit incorporated for calculating the angular velocity based on the output of sensor element 18.

FIG. 3 illustrates a schematic perspective view of sensor element 18 and substrate 12. In sensor 10, the area of each of sensor electrodes 18A is smaller in a portion closer to main face 50 of substrate 12. In other words, sensor electrode 18A of sensor 10 has a triangular shape. In other words, sensor electrode 18A of sensor 10 has a tapered shape. In other words, sensor electrode 18A of sensor 10 has a shape having a width which is reduced toward main face 50 of substrate 12.

Such a structure reduces, for example, the possibility of chipping which occurs when sensor element 18 is divided. Hereinafter, the structure and effects will be specifically described.

In a conventional sensor element, if the sensor electrodes extend to the end face of the sensor element, chipping (electrode peeling) may occur when the sensor element is divided. Therefore, it is difficult to reduce the distance between the sensor electrodes and the end face of the sensor element. In other words, the sensor electrodes in the conventional sensor element do not extend to the end face of the sensor element, and a given distance is disposed between the sensor electrodes and the end face of the sensor element. Therefore, when the sensor element is perpendicularly mounted on the substrate, connection members (solders) are not sufficiently filled between the sensor electrodes and the substrate electrodes, which may result in defective joining.

In contrast, in the present embodiment, sensor electrodes 18A extend to the end face of sensor element 18. As a result, the connection members (solders) are sufficiently filled between sensor electrodes 18A and substrate electrodes 35. Moreover, the area of each of sensor electrodes 18A is smaller at the end face of sensor element 18 (at the position closer to main face 50 of substrate 12). In other words, the width of sensor electrode 18A is reduced toward main face 50. In other words, sensor electrode 18A has a triangular shape having a vertex angle toward main face 50. Therefore, dividing is less likely to cause chipping (electrode peeling). Since the width of sensor electrode 18A at the end face of sensor element 18 is small, even if the tip of sensor electrode 18A is slightly scraped, sensor electrode 18A itself does not peel off. Here, the term “dividing” indicates, for example, after connecting a plurality of sensor elements 18 to substrate 12, cutting sensor elements 18 into individual sensor elements 18.

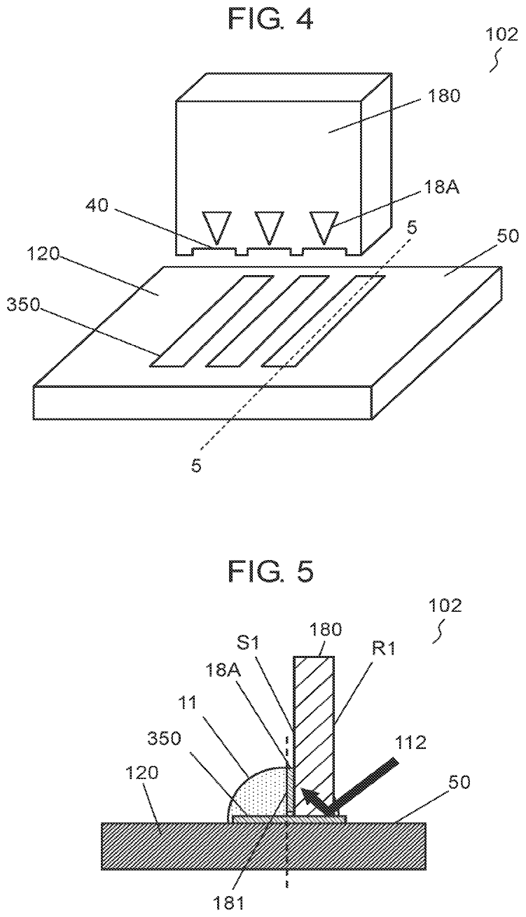

FIG. 4 is an exploded schematic perspective view of another sensor element 180 and substrate 120 according to the embodiment. FIG. 5 is a schematic cross-sectional view taken along line 5-5 in a state where substrate 120 and sensor element 180 in FIG. 4. are combined. In other words, FIG. 4 is a schematic perspective view of a state before substrate 120 and sensor element 180 are joined. FIG. 5 is a cross-sectional view of a state after substrate 120 and sensor element 180 are joined. Sensor 102 includes substrate electrodes 350 longer than substrate electrodes 35 of sensor 10.

As illustrated in FIG. 5, substrate electrodes 350 of sensor 102 extend to sensor element 180 beyond surface 181 of sensor electrodes 18A (plane passing through the broken line in FIG. 5). Moreover, each of substrate electrodes 350 of sensor 102 extends outwardly beyond rear face R1 of sensor element 180 (the face opposite to first face 51 on which sensor electrodes 18A are disposed). In other words, substrate electrodes 350 extend in a direction which penetrates sensor element 180. Moreover, sensor element 180 has grooves 40 through which sensor electrodes 18A pass.

With this structure, for example, sensor electrodes 18A function as reflective layers for laser light 112. As a result, it is possible to prevent laser light 112 from entering substrate 120. More specifically, when laser light 112 is emitted from the rear side of sensor element 180 in order to melt solders 11, the emitting position of laser light 112 may deviate, causing laser light 112 to enter substrate 120. In this case, the inside of substrate 120 may be damaged or defective joining due to insufficient heat may be caused. However, since sensor electrodes 18A of sensor 102 function as reflecting layers for laser light 112, it is possible to prevent laser light 112 from entering substrate 120.

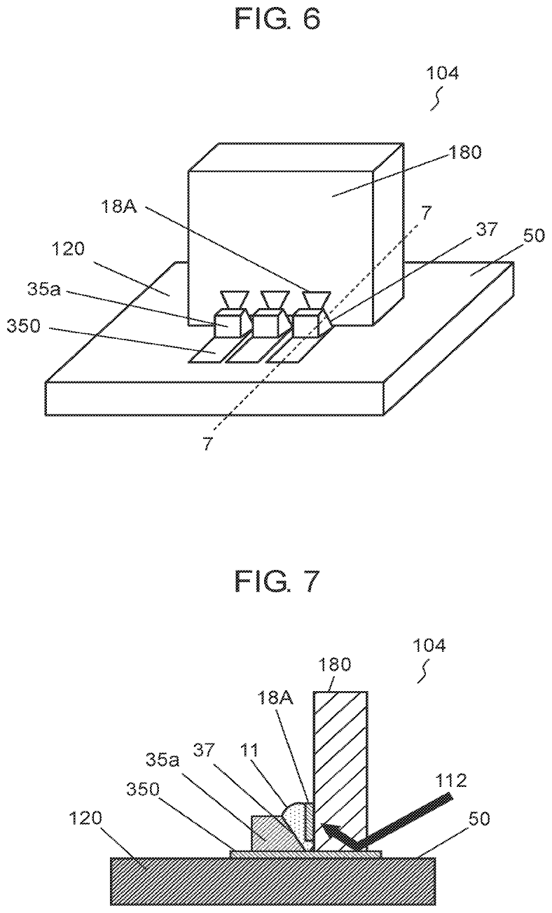

FIG. 6 is a schematic perspective view of yet another sensor element 180 and substrate 120 according to the embodiment. FIG. 7 is a schematic cross-sectional view taken along line 7-7 in FIG. 6. Sensor 104 includes post electrodes 35a connected to substrate electrodes 350.

Each of post electrodes 35a has a cutout shape in which a portion of a prism which is in contact with sensor element 180 is cut out. In other words, post electrode 35a has an inclined face (or hypotenuse) whose distance from sensor electrode 18A is larger at a position farther from main face 50 of substrate 120. In other words, post electrode 35a has inclined face 37 (or hypotenuse) on the side opposing sensor element 180. Note that the inclined face (or hypotenuse) is not limited to a linear face. In other words, the inclined face (or hypotenuse) may include a curved line, a curved face and/or an uneven face. Moreover, post electrode 35a may have a shape in which a cylinder is partially cut out.

Solder 11 is filled over sensor electrode 18A of sensor element 180 and the cut out portion of post electrode 35a. As a result, sufficient joining strength can be obtained.

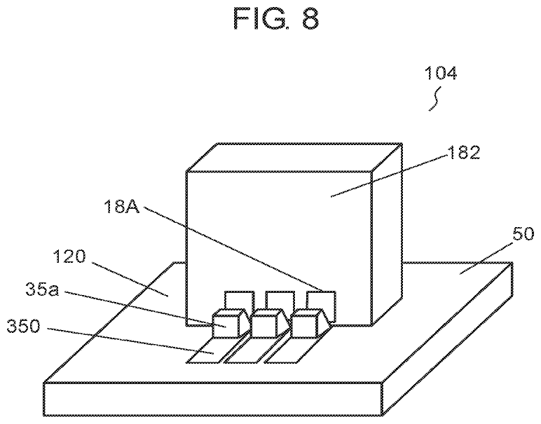

FIG. 8 is a schematic perspective view of yet another sensor element 182 and substrate 120 according to the embodiment. In the case where post electrodes 35a are disposed, sensor electrodes 18A and substrate electrodes 350 can obtain sufficient contact. Therefore, as illustrated in FIG. 8, sensor electrodes 18A each may have, for example, a quadrangular shape instead of a triangular shape.

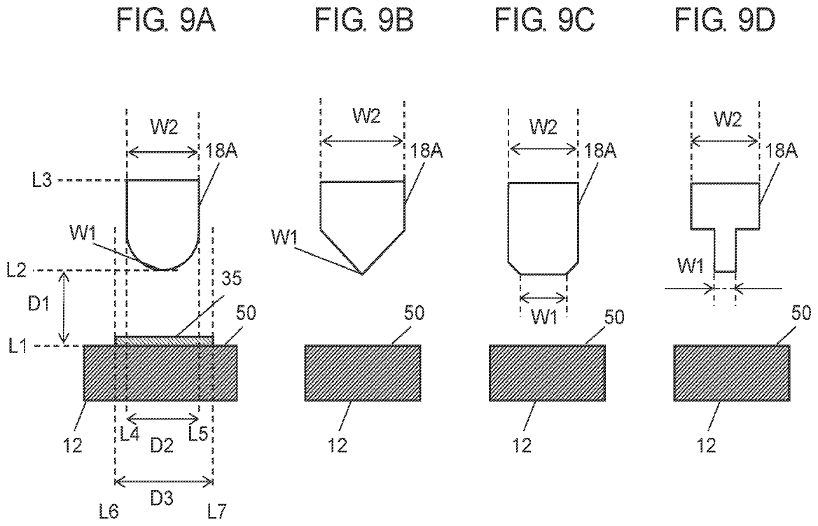

FIG. 9A to FIG. 9D illustrate variations of sensor electrode 18A according to the embodiment. As illustrated in FIG. 9A, sensor electrode 18A may have a shape rounded toward main face 50 of substrate 12. As illustrated in FIG. 9B, sensor electrode 18A may have a pentagonal shape. As illustrated in FIG. 9C, sensor electrode 18A may have a hexagonal shape. As illustrated in FIG. 9D, sensor electrode 18A may have a projecting shape. In other words, sensor electrode 18A may have a polygonal shape.

In other words, the shape of sensor electrode 18A is that width W1 of sensor electrode 18A at a position closer to main face 50 of substrate 12 (the width of sensor electrode 18A at a position in contact with straight line L2 in FIG. 9A) is smaller than width W2 of sensor electrode 18A at a position farther from main face 50 of substrate 12 (the width of sensor electrode 18A at a position in contact with straight line L3 in FIG. 9A). It should be noted that the terms “farther” and “closer” here are not construed as limiting the meaning of the “farthest” and “closest”. Note that the term “width” here includes the case of “point”.

The shape of sensor electrode 18A can be expressed in another way. Specifically, it can be described as follows. First, two straight lines L2 and L3 are defined as virtual straight lines parallel to main face 50 of substrate 12. Here, the distance between straight line L2 and main face 50 of substrate 12 is smaller than the distance between straight line L3 and main face 50 of substrate 12. The width of the portion of straight line L2 passing through sensor electrode 18A is smaller than the width of the portion of straight line L3 passing through sensor electrode 18A.

Note that a gap which is distance D1 may be disposed between main face 50 of substrate 12 and the bottom end of sensor electrode 18A.

Note that straight lines L4 to L7 are virtual lines perpendicular to the main face of substrate 12. In the cross-section parallel to main face 50 of electrode 18A, it is preferable that width D3 of substrate electrode 35 is larger than width D2 of sensor electrode 18A. With this structure, defective joining can be further reduced.

It is to be noted that instead of solder 11, an electrically conductive paste in which metal powder made of Ag or the like is added to a resin material may be used. In other words, solder 11 can be read as an electrically conductive connection member.

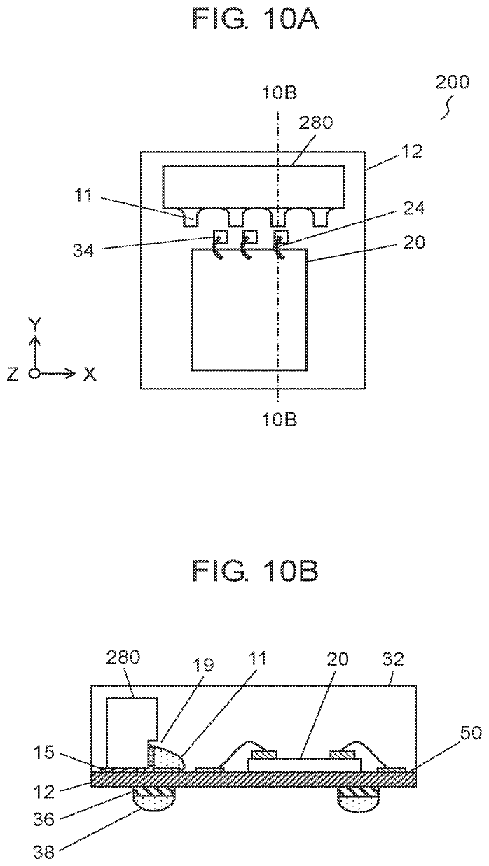

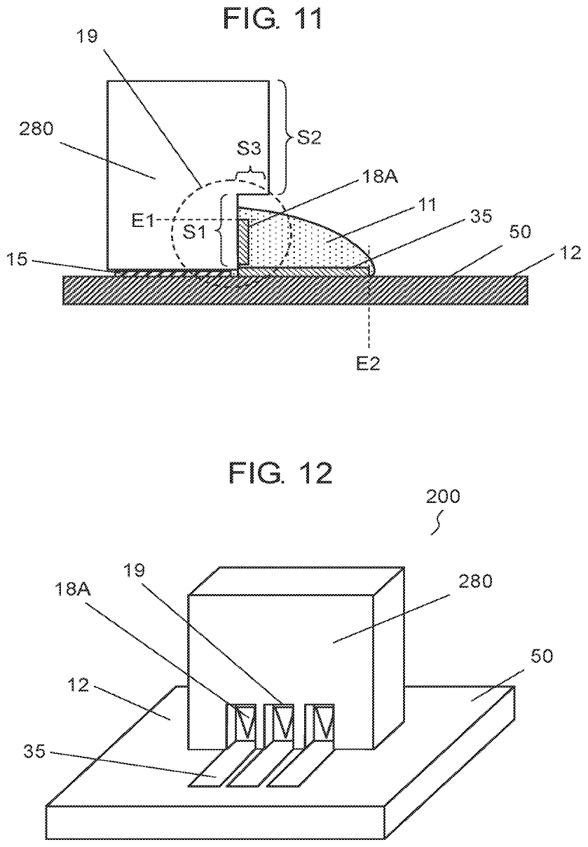

FIG. 10A is a top view of yet another sensor 200 according to the embodiment. FIG. 10B illustrates a cross-section taken along line 10B-10B in FIG. 10A. FIG. 11 is a schematic cross-sectional view of sensor element 280 and substrate 12 according to the embodiment. FIG. 12 is a schematic perspective view of sensor element 280 and substrate 12 according to the embodiment. Step portions 19 are disposed by recessing portions of sensor element 280. Sensor electrodes 18A of sensor element 280 are disposed on the surfaces of step portions 19.

In other words, sensor element 280 includes first face 51, and second face S2 which protrudes beyond first face 51.

In other words, sensor element 280 has third face S3 opposing main face 50 of substrate 12.

Sensor electrodes 18A are disposed on first face 51 of sensor element 280. Moreover, sensor electrodes 18A each have end E1 opposing third face S3 of sensor element 280.

Substrate electrodes 35 are disposed on main face 50 of substrate 12. Substrate electrodes 35 each have end E2.

The contact point between solder 11 and sensor element 280 is disposed on first face 51.

In other words, the contact point between sensor element 280 and solder 11 is disposed between third face S3 or second face S2 and end E1. Moreover, solder 11 covers end E2.

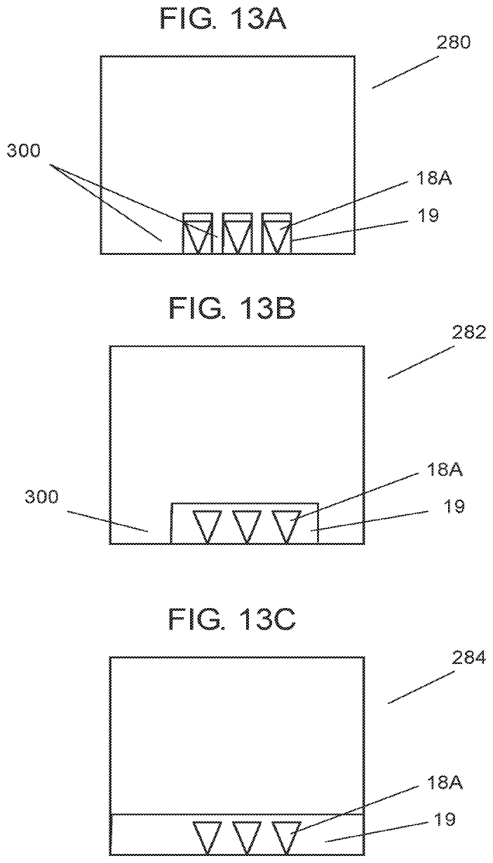

FIG. 13A is a front view of sensor element 280 according to the embodiment. FIG. 13B is a front view of sensor element 282 according to the embodiment. FIG. 13C is a front view of sensor element 284 according to the embodiment. In FIG. 13A, step portion 19 is disposed for each sensor electrode 18A. However, as illustrated in FIG. 13B and FIG. 13C, step portion 19 does not have to be disposed for each sensor electrode 18A. However, as illustrated in FIG. 13A and FIG. 13B, sensor element can be stably mounted on substrate 12 by including legs 300. Therefore, the structures of sensor element 280 and sensor element 282 are preferable to the structure of sensor element 284. Moreover, as illustrated in FIG. 13A, the sensor element can be mounted on substrate 12 more stably by including legs 300 between sensor electrodes 18A. Therefore, the structure of sensor element 280 is preferable to the structure of sensor element 282.

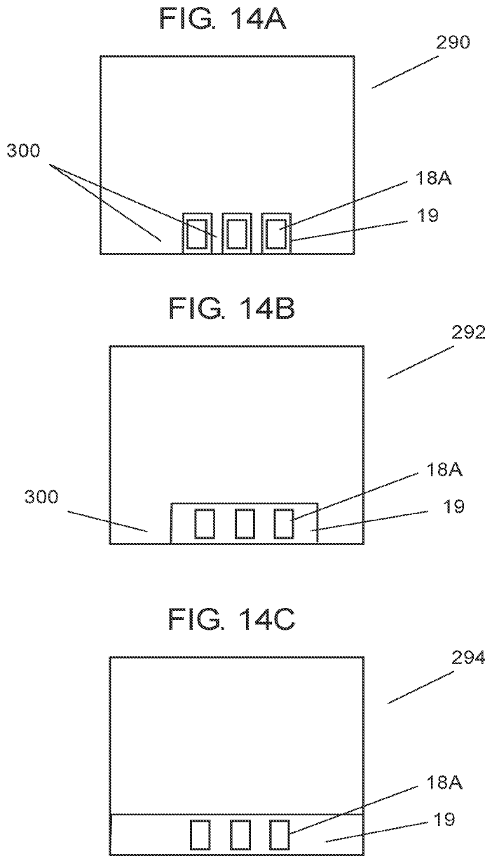

In view of the stable mounting of the sensor element on substrate 12, the shape of each sensor electrode 18A is not limited to a triangular shape, but may be, for example, a quadrangular shape, a polygonal shape, or an elliptical shape. FIG. 14A is a front view of sensor element 290 according to the embodiment. FIG. 14B is a front view of sensor element 292 according to the embodiment. FIG. 14C is a front view of sensor element 294 according to the embodiment. The other structures of sensor elements 290, 292, 294 are substantially the same as the structure of sensor element 280. As illustrated in FIG. 14A to FIG. 14C, sensor elements 290, 292, 294 may be used which have quadrangular sensor electrodes 18A and step portions 19.

Note that substrate electrodes 35 are not limited to the shapes illustrated in FIG. 11 and FIG. 12, but, for example, as illustrated in FIG. 4, may extend outwardly beyond the rear face of the sensor element. In other words, substrate electrodes 35 may extend in a direction which penetrates the sensor element. Moreover, the number of sensor electrodes 18A is not limited to three, but may be any number.

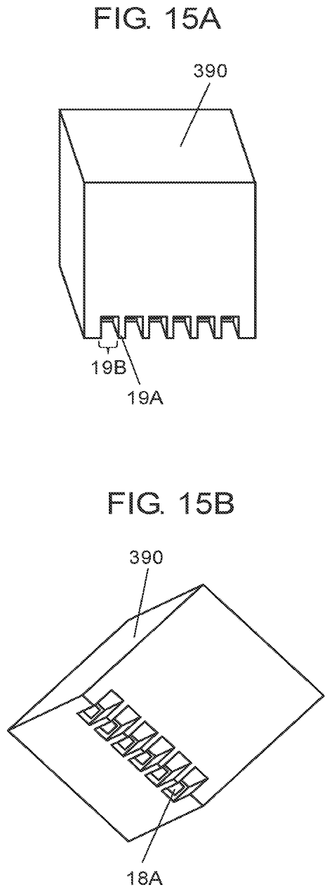

FIG. 15A is an oblique projection view of sensor element 390 according to the embodiment. FIG. 15B is an oblique projection view of sensor element 390 viewed from the bottom side of sensor element 390 according to the embodiment. Sensor element 390 includes six step portions in the structure of sensor element 290.

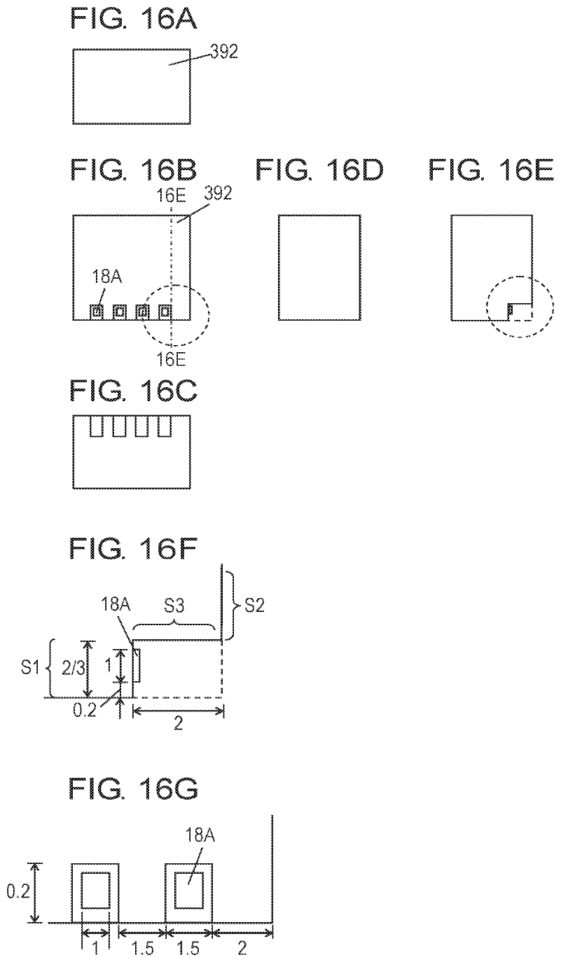

FIG. 16A is a top view of sensor element 392. FIG. 16B is a front view of sensor element 392. FIG. 16C is a bottom view of sensor element 392. FIG. 16D is a side view of sensor element 392. FIG. 16E is a cross-sectional view taken along line 16E-16E in FIG. 16B. FIG. 16F is an enlarged view of the area circled by the dashed line in FIG. 16E. FIG. 16G is an enlarged view of the area circled by the dashed line in FIG. 16B. The values in FIG. 16F and FIG. 16G indicate the relative size of each element with the width of sensor electrode 18A being 1. Sensor element 392 includes four step portions in the structure of sensor element 290.

This structure can reduce the problem in that adjacent solders 11 are short-circuited. In other words, sensor elements 280, 290, 390, and 392 have walls 19A which provide partitions between sensor electrodes 18A. In other words, sensor elements 280, 290, 390, and 392 include recesses 19B which house sensor electrodes 18A. Sensor electrodes 18A are respectively housed in recesses 19B. Here, recesses 19B may be expressed as cutout portions. Instead of solders 11, electrically conductive pastes in which metal powder made of Ag or the like is added to a resin material may be used. In other words, solders 11 can be read as electrically conductive connection members.

As described above, the sensor according to the present disclosure is capable of increasing the reliability of joining between the sensor element and the substrate. Moreover, the sensor element can be stably and perpendicularly mounted on the substrate.

### INDUSTRIAL APPLICABILITY

The sensor according to the present disclosure is excellent in reliability and stability, and is useful as a sensor used in, for example, an electronic device.

### REFERENCE MARKS IN THE DRAWINGS

10, 102, 104, 200 sensor
11 solder (connection member)
12, 120 substrate
15 adhesive material
18, 180, 182, 280, 282, 284, 290, 390, 392 sensor element
18A sensor electrode
19 step portion
20 semiconductor element
24 metal thin line
32 sealing resin
34 pad
35, 350 substrate electrode
35a post electrode
36 bottom electrode
37 inclined face
38 solder bump
40 groove
50 main face
52, 53 bottom face
54 apex
56 line segment
112 laser light
181 surface
E1, E2 end
R1 rear face
S1 first face
S2 second face
S3 third face
W1, W2 width

1. A sensor comprising:
a substrate having a main face;
a substrate electrode disposed on the main face;
a sensor element which has a first face perpendicular to the main face, and detects an angular velocity about an axis parallel to the main face;
a sensor electrode disposed on the first face of the sensor element;
a connection member which connects the substrate electrode and the sensor electrode; and
a post electrode connected to the substrate electrode, wherein:
a width of the sensor electrode at a position closer to the main face is smaller than a width of the sensor electrode at a position farther from the main face, and
the post electrode has a cutout shape in which a portion of the post electrode in contact with the sensor element is cut out.

2. A sensor comprising:
a substrate having a main face;
a substrate electrode disposed on the main face;
a sensor element which has a first face perpendicular to the main face, and detects an angular velocity about an axis parallel to the main face;
a sensor electrode disposed on the first face of the sensor element;
a connection member which connects the substrate electrode and the sensor electrode; and
a post electrode connected to the substrate electrode, wherein:
a width of the sensor electrode at a position closer to the main face is smaller than a width of the sensor electrode at a position farther from the main face, and
the post electrode has an inclined face opposing the first face.
